(19) United States
(12) Patent Application Publication
(10) Pub. No.: US 2022/0285578 A1
(43) Pub. Date: Sep. 8, 2022

(54) LIGHT-EMITTING DIODE AND DISPLAY DEVICE INCLUDING THE SAME

(71) Applicant: SAMSUNG ELECTRONICS CO., LTD., Suwon-si (KR)

(72) Inventors: Dongho KIM, Seoul (KR); Kyungwook Hwang, Seoul (KR)

(73) Assignee: SAMSUNG ELECTRONICS CO., LTD., Suwon-si (KR)

(21) Appl. No.: 17/478,468

(22) Filed: Sep. 17, 2021

Related U.S. Application Data
(60) Provisional application No. 63/157,972, filed on Mar. 8, 2021.

(30) Foreign Application Priority Data
May 25, 2021 (KR) 10-2021-0066830

(51) Int. Cl. H01L 33/06; H01L 33/10; H01L 25/075; H01L 27/15; H01L 33/00; H01L 25/16; H01L 25/18

(52) U.S. Cl. CPC H01L 33/06; H01L 33/10; H01L 25/0756; H01L 27/15; H01L 33/0093; H01L 25/167; H01L 25/18; H01L 33/38

(57) ABSTRACT

Provided is a light-emitting diode including a first-light emitting cell, a second light-emitting cell, and a third light-emitting cell that are sequentially provided in one direction and configured to emit light of different colors from each other, a first tunnel junction provided between the first light-emitting cell and the second light-emitting cell, the first tunnel junction being configured to electrically connect the first light-emitting cell and the second light-emitting cell and induce lateral current spreading, and a second tunnel junction provided between the second light-emitting cell and the third light-emitting cell, the second tunnel junction being configured to electrically connect the second light-emitting cell and the third light-emitting cell and induce lateral current spreading.

### CROSS-REFERENCE TO RELATED APPLICATIONS

This application claims the benefit of U.S. Provisional Application No. 63/157,972, filed on Mar. 8, 2021, in the US Patent Office and Korean Patent Application No. 10-2021-0066830, filed on May 25, 2021, in the Korean Intellectual Property Office, the disclosures of which are incorporated herein in their entireties by reference.

### BACKGROUND

### 1. Field

Example embodiments of the present disclosure relate to light-emitting diodes and display devices, and more particularly, to light-emitting diodes emitting light of different colors from each other according to electrode connection in a light-emitting diode chip and display devices including the same.

### 2. Description of Related Art

Recently, a prototype light-emitting diode (LED) display is a display of a self-luminous structure in which a light-emitting diode in units of μm is mounted at a pixel position of a driving substrate, and has advantages, such as high brightness, high power efficiency, a long lifespan, and implementation of various form factors. An LED display may implement full color based on image information through designation of red light R, green light G, and blue light B. For full color implementation, an RGB color display method may be used, in which R, G, and B LEDs are transferred to each pixel of a driving substrate. Alternatively, a method of using color conversion layers in which the color conversion layers corresponding to each of sub-pixels corresponding to red light and green light are additionally formed after transferring a B LED to all pixels of the driving substrate.

The RGB color display method has disadvantages in that the arrangement of R, G, and B LEDs in each of hundreds of thousands of pixels on a panel has a high cost. The method of using color conversion layers uses phosphor and quantum dots (QD) in manufacturing the color conversion layer. In this case, there are disadvantages that the lifespan of a panel is reduced because phosphor is deteriorated by heat and the cost for QD coating is higher than when each light source of the three primary colors is used.

### SUMMARY

One or more example embodiments provide monolithic growth light-emitting diodes capable of implementing characteristics for emitting light of first to third colors.

One or more example embodiments also provide light-emitting diodes capable of selectively emitting light of first to third colors according to electrode connection.

One or more example embodiments provide display devices that realize a full color without arranging light-emitting diodes that emit light of different colors or without using color conversion layers.

Additional aspects will be set forth in part in the description which follows and, in part, will be apparent from the description, or may be learned by practice of example embodiments of the disclosure.

According to an aspect of an example embodiment, there is provided a light-emitting diode including a first-light emitting cell, a second light-emitting cell, and a third light-emitting cell that are sequentially provided in one direction and configured to emit light of different colors from each other, a first tunnel junction provided between the first light-emitting cell and the second light-emitting cell, the first tunnel junction being configured to electrically connect the first light-emitting cell and the second light-emitting cell and induce lateral current spreading, and a second tunnel junction provided between the second light-emitting cell and the third light-emitting cell, the second tunnel junction being configured to electrically connect the second light-emitting cell and the third light-emitting cell and induce lateral current spreading.

The light-emitting diode may further include a first electrode in contact with the first light-emitting cell, a second electrode in contact with the second light-emitting cell, and a third electrode and a fourth electrode spaced apart from each other and in contact with the third light-emitting cell.

The first electrode, the second electrode, the third electrode, and the fourth electrode may be symmetrical with respect to a central axis of the light-emitting diode.

Cross-sectional shapes of the first electrode, the second electrode, and the third electrode may be ring-shapes, and a cross-sectional shape of the fourth electrode may be one of a circular shape, an oval shape, a polygonal shape, and a ring shape.

Two adjacent electrodes from among the first electrode, the second electrode, the third electrode, and the fourth electrode may be electrically connected to electrode pads of a driving layer based on at least one of soldering, anisotropic conductive film (ACF), or attachment using a conducting wire.

When the first electrode and the second electrode are electrically connected, the first light-emitting cell may be configured to emit light of a first color, when the second electrode and the third electrode are electrically connected, the second light-emitting cell may be configured to emit light of a second color, or when the third electrode and the fourth electrode are electrically connected, the third light-emitting cell may be configured to emit light of a third color.

The light of the first color may be red light, the light of the second color may be green light, and the light of the third color may be blue light.

The light-emitting diode may be configured to emit light of one color by electrically connecting one pair of two adjacent electrodes from among the first electrode, the second electrode, the third electrode, and the fourth electrode to a driving layer.

The light-emitting diode may further include at least one of a first compositionally graded layer under the first light-emitting cell, a second compositionally graded layer between the first light-emitting cell and the second light-emitting cell, and a third compositionally graded layer between the second light-emitting cell and the third light-emitting cell.

The light-emitting diode may further include a first electrode in contact with the first compositionally graded layer, a second electrode in contact with the second compositionally graded layer, a third electrode in contact with the third compositionally graded layer, and a fourth electrode in contact with the third light-emitting cell.

The light-emitting diode may further include at least one of a first distributed Bragg reflector (DBR) layer provided on the first light-emitting cell and configured to reflect light of a second color emitted from the second light-emitting cell, a second DBR layer provided on the second light-emitting cell and configured to reflect light of a third color emitted from the third light-emitting cell, or a third DBR layer provided under the first light-emitting cell and configured to reflect light of a first color emitted from the first light-emitting cell.

A width of the first light-emitting cell may be greater than a width of the second light-emitting cell, and the width of the second light-emitting cell may be greater than a width of the third light-emitting cell.

According to another aspect of an example embodiment, there is provided a display device including a display layer including a plurality of light-emitting diodes, and a driving layer including a plurality of transistors electrically connected to the plurality of light-emitting diodes and configured to drive the plurality of light-emitting diodes, wherein at least one of the plurality of light-emitting diodes includes a first light-emitting cell, a second light-emitting cell, and a third light-emitting cell sequentially provided in one direction and configured to emit light of different colors from each other, a first tunnel junction provided between the first light-emitting cell and the second light-emitting cell, the first tunnel junction being configured to electrically connect the first light-emitting cell and the second light-emitting cell and induce lateral current spreading, and a second tunnel junction provided between the second light-emitting cell and the third light-emitting cell, the second tunnel junction being configured to electrically connect the second light-emitting cell and the third light-emitting cell and induce lateral current spreading.

The display device may further include a first electrode in contact with the first light-emitting cell, a second electrode in contact with the second light-emitting cell, and a third electrode and a fourth electrode spaced apart from each other and in contact with the third light-emitting cell.

When the first electrode and the second electrode are electrically connected, the first light-emitting cell may be configured to emit light of a first color, when the second electrode and the third electrode are electrically connected, the second light-emitting cell may be configured to emit light of a second color, and when the third electrode and the fourth electrode are electrically connected, the third light-emitting cell may be configured to emit light of a third color.

The display device may further include at least one of a first compositionally graded layer under the first light-emitting cell, a second compositionally graded layer between the first light-emitting cell and the second light-emitting cell, and a third compositionally graded layer between the second light-emitting cell and the third light-emitting cell.

The display device may further include a first electrode in contact with the first compositionally graded layer, a second electrode in contact with the second compositionally graded layer, a third electrode in contact with the third compositionally graded layer, and a fourth electrode in contact with the third light-emitting cell.

The driving layer may include a first region, a second region, and a third region that are alternately provided, each of the first region, the second region, and the third region may include at least one well, and the plurality of light-emitting diodes provided in each well of the first region, the second region, and the third region may be configured to emit light of different colors based on the provided regions, respectively.

According to another aspect of an example embodiment, there is provided a method of manufacturing a monolithic growth light-emitting diode configured to selectively emit one of first color light, second color light, and third color light based on connection of a first electrode, a second electrode, a third electrode, and a fourth electrode, the method including growing a first compositionally graded layer on a substrate, growing a first light-emitting cell on the first compositionally graded layer, sequentially forming a first tunnel junction and a first diffraction Bragg reflector (DBR) layer on the first light-emitting cell, growing a second compositionally graded layer on the first DBR layer, growing a second light-emitting cell on the second compositionally graded layer, sequentially forming a second tunnel junction and a second DBR layer on the second light-emitting cell, growing a third compositionally graded layer on the second DBR layer, growing a third light-emitting cell on the third compositionally graded layer, and forming the first electrode, the second electrode, and the third electrode in contact with the first compositionally graded layer, the second compositionally graded layer, and the third compositionally graded layer, respectively, and forming the fourth electrode on the third light-emitting cell.

According to another aspect of an example embodiment, there is provided a method of manufacturing a heterogeneous substrate bonding light-emitting diode configured to emit one of first color light, second color light, and third color light based on connection of a first electrode, a second electrode, a third electrode, and a fourth electrode, the method including growing a first element, growing a second element, bonding the first element and the second element, removing a second substrate of the second element, and forming an electrode, wherein the growing of the first element includes forming a third diffraction Bragg reflector (DBR) layer on a first substrate, growing a first light-emitting cell on the third DBR layer, and forming a first tunnel junction on the first light-emitting cell, wherein the growing of the second element includes growing a third compositionally graded layer on the second substrate, growing a third light-emitting cell on the third compositionally graded layer, growing a second compositionally graded layer on the third light-emitting cell, sequentially forming a second DBR layer and a second tunnel junction on the second compositionally graded layer, growing a second light-emitting cell on the second tunnel junction, and forming a first DBR layer on the second light-emitting cell, and wherein the forming of the electrode includes forming the first electrode, the second electrode, and the third electrode in contact with the first light-emitting cell, the second light-emitting cell, and the third light-emitting cell, respectively, and forming the fourth electrode on the third light-emitting cell.

### BRIEF DESCRIPTION OF THE DRAWINGS

The above and/or other aspects, features, and advantages of example embodiments of the disclosure will be more apparent from the following description taken in conjunction with the accompanying drawings, in which:

FIG. 1 is a cross-sectional view seen from a side of a light-emitting diode according to an example embodiment;

FIG. 2 is a cross-sectional view seen from top of a light-emitting diode according to an example embodiment;

FIG. 3A is a diagram illustrating a connection between second and third electrodes and a driving layer of a light-emitting diode according to an example embodiment;

FIG. 3B illustrates a connection between first and second electrodes and a driving layer of a light-emitting diode according to an example embodiment;

FIG. 3C illustrates a connection between third and fourth electrodes and a driving layer of a light-emitting diode according to an example embodiment;

FIG. 4 is a cross-sectional view seen from a side of a light-emitting diode according to another example embodiment;

FIGS. 5A, 5B, and 5C illustrate a method of manufacturing a monolithic growth light-emitting diode on a single substrate, according to an example embodiment;

FIGS. 6A, 6B, 6C, and 6D illustrate a method of manufacturing a light-emitting diode by bonding a first element and a second element respectively grown on a heterogeneous substrate, according to another example embodiment;

FIG. 7 is a diagram illustrating a cross-section view seen from top of a driving layer including a plurality of wells; according to an example embodiment

FIG. 8 is a diagram illustrating a display device including a light-emitting diode according to an example embodiment;

FIG. 9 illustrates an example in which a display device according to an example embodiment is applied to a mobile device;

FIG. 10 illustrates an example in which a display device according to an example embodiment is applied to an automobile;

FIG. 11 illustrates an example in which a display device according to an example embodiment is applied to augmented reality glasses or virtual reality glasses;

FIG. 12 illustrates an example in which a display device according to an example embodiment is applied to a large signage; and

FIG. 13 illustrates an example in which a display device according to an example embodiment is applied to a wearable display.

### DETAILED DESCRIPTION

Reference will now be made in detail to example embodiments of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments will be described in detail with reference to the accompanying drawings. The example embodiments of the inventive concept are capable of various modifications and may be embodied in many different forms. In the drawings, like reference numerals refer to like elements throughout, and sizes of elements in the drawings may be exaggerated for clarity and convenience of explanation.

When an element or layer is referred to as being “on” or “above” another element or layer, the element or layer may be directly on another element or layer or intervening elements or layers. Likewise, when an element or layer is referred to as being “below” or “under” another element or layer, the element or layer may be directly under another element or layer or intervening elements or layers.

The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural.

The term “connection” may include not only a physical connection, but also an optical connection, an electrical connection, and the like.

All examples or example terms (for example, etc.) are simply used to explain in detail the technical scope of the inventive concept, and thus, the scope of the inventive concept is not limited by the examples or the example terms as long as it is not defined by the claims.

Although the terms “first,” “second,” etc. may be used herein to describe various constituent elements, these constituent elements should not be limited by these terms. These terms are only used to distinguish one constituent element from another.

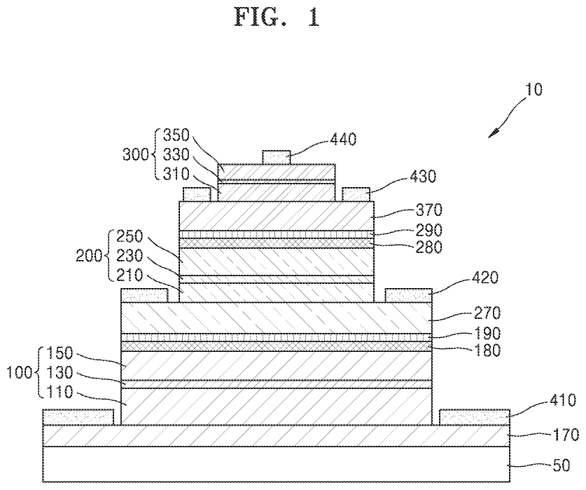

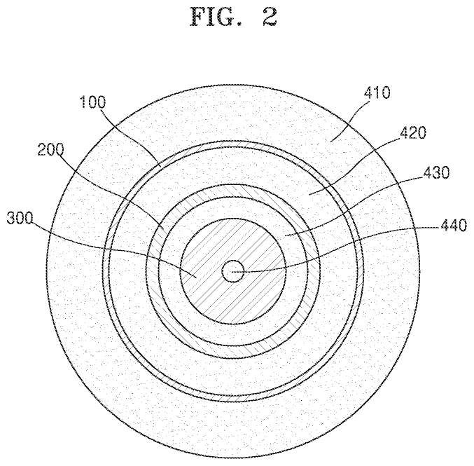

FIG. 1 is a cross-sectional view seen from a side of a light-emitting diode 10 according to an example embodiment. FIG. 2 is a cross-sectional view seen from top of the light-emitting diode 10 according to an example embodiment.

Referring to FIGS. 1 and 2, the light-emitting diode 10 according to an example embodiment may include a first light-emitting cell 100, a second light-emitting cell 200, and a third light-emitting cell 300 that are sequentially arranged in one direction and emit light of different colors, respectively. A first tunnel junction 180 is arranged between the first light-emitting cell 100 and second light-emitting cell 200, electrically connects the first light-emitting cell 100 and second light-emitting cell 200, and induces lateral current spreading between the first light-emitting cell 100 and the second light-emitting cell 200. A second tunnel junction 280 is arranged between the second light-emitting cell 200 and third light-emitting cell 300, electrically connects the second light-emitting cell 200 and third light-emitting cell 300, and induces lateral current diffusion between the second light-emitting cell 200 and the third light-emitting cell 300. Also, the light-emitting diode 10 according to an example embodiment may include at least one of a first compositionally graded layer 170 under the first light-emitting cell 100, a second compositionally graded layer 270 between the first light-emitting cell 100 and second light-emitting cell 200, and a third compositionally graded layer 370 between the second light-emitting cell 200 and third light-emitting cell 300. The light-emitting diode 10 according to an example embodiment may include a first electrode 410, a second electrode 420, a third electrode 430, and a fourth electrode 440. The first electrode 410 may be in contact with the first compositionally graded layer 170, the second electrode 420 may be in contact with the second compositionally graded layer 270, the third electrode 430 may be in contact with the third compositionally graded layer 370, and the fourth electrode 440 may be in contact with the third light-emitting cell 300. A current may selectively flow through one of the first light-emitting cell 100, the second light-emitting cell 200, or the third light-emitting cell 300 by connecting adjacent two electrodes from among the first to fourth electrodes 410, 420, 430, and 440, and accordingly, light may be emitted from active layers 130, 230, or 330 of the corresponding light-emitting cells.

The light-emitting diode 10 according to an example embodiment may have a micro-unit size. For example, the size of the light-emitting diode 10 may have a size in a range of about 1 μm to about 1000 μm. The light-emitting diode 10 may have a size of about 200 μm or less.

The light-emitting diode 10 according to an example embodiment may further include a substrate 50 below the first light-emitting cell 100. On the substrate 50, the first light-emitting cell 100, the second light-emitting cell 200, and the third light-emitting cell 300 may be grown. If the lattice constant of the substrate 50 and the lattice constant of the first light-emitting cell 100 arranged on the substrate 50 are the same, the first light-emitting cell 100 may be arranged on the substrate 50 while contacting the substrate 50. When lattice constant of the substrate 50 and the lattice constant of the first light-emitting cell 100 arranged on the substrate 50 are not the same, a lattice constant difference between the substrate 50 and the first light-emitting cell 100 may be compensated by arranging the first compositionally graded layer 170 between the substrate 50 and the first light-emitting cell 100. The substrate 50 may include silicon (Si), sapphire (Al₂O₃), gallium arsenide (GaAs), and the like. For example, when the substrate 50 includes Si or sapphire and the light-emitting cell 100 includes InₓGa₁₋ₓN (0≤x≤1) that emits red light, because the lattice constants are not the same, the first compositionally graded layer 170 may be included between the substrate 50 and the light-emitting cell 100. For example, when the substrate 50 includes GaAs and the first light-emitting cell 100 includes AlₚGa_{q}In_{1-p-q}P (0≤p≤1, 0≤q≤1, 0≤p+q≤1) that emits red light, the lattice constants of the substrate 50 and the first light-emitting cell 100 are substantially the same, and thus, the first light-emitting cell 100 may be arranged on the substrate 50 without the first compositionally graded layer 170. The substrate 50 may be removed after the first light-emitting cell 100, the second light-emitting cell 200, and the third light-emitting cell 300 are grown.

The first compositionally graded layer 170, the second compositionally graded layer 270 and the third compositionally graded layer 370 are layers for compensating a lattice constant difference when the lattice constants of a material below the layers and a material above the layers are not the same. By changing a lattice constant according to thickness, the first compositionally graded 170, the second compositionally graded layer 270, and the third compositionally graded layer 370 may connect two layers on which lattice-matched epitaxial growth may not be possible due to a lattice constant difference. Therefore, when the first compositionally graded layer 170, the second compositionally graded layer 270, and the third compositionally graded layer 370 are placed between layers that do not have the same lattice constant as each other, epitaxial growth of layer having a different lattice constant may be possible. The first compositionally graded layer 170, the second compositionally graded layer 270, and the third compositionally graded layer 370 may include the same elements as each epitaxial layer. For example, the first compositionally graded layer 170 may include the same elements as the first-emitting cell 100 grown on the first compositionally graded layer 170. According to another example, the first compositionally graded layer 170, the second compositionally graded layer 270, and the third compositionally graded layer 370 may include different elements with each epitaxial layer. Even when the first compositionally graded layer 170, the second compositionally graded layer 270, and the third compositionally graded layer 370 include the same elements, a composition ratio may be different depending on a thickness thereof, and the lattice constants may be different according to the composition ratio. For example, when the first compositionally graded layer 170, the second compositionally graded layer 270, and the third compositionally graded layer 370 include InₛGa₁₋ₛN (0≤s≤1), s gradually changes according to the thickness, and thus, the lattice constant may increase or decrease for each layer height. Accordingly, each lowermost layer of the first compositionally graded layer 170, the second compositionally graded layer 270, and the third compositionally graded layer 370 may have the same lattice constant as each layer under the first compositionally graded layer 170, the second compositionally graded layer 270, and the third compositionally graded layer 370. Each uppermost layer of the first compositionally graded layer 170, the second compositionally graded layer 270, and the third compositionally graded layer 370 may have the same lattice constant as each layer on the first compositionally graded layer 170, the second compositionally graded layer 270, and the third compositionally graded layer 370.

When the light-emitting diode 10 according to an example embodiment is a monolithic growth light-emitting diode in which the plurality of light-emitting cells 100, 200, and 300 are grown on a single substrate 50, the number of compositionally graded layers included in the light-emitting diode 10 may be equal to or less than the number of the grown light-emitting cells. For example, the light-emitting diode 10 of FIG. 1 includes three cells, that is, the first light-emitting cell 100, the second light-emitting cell 200, and the third light-emitting cell 300, and may include three layers, that is, the first compositionally graded layer 170, the second compositionally graded layer 270, and the third compositionally graded layer 370. However, if another material having the same lattice constant with one material is grown on the one material, a compositionally graded layer may not be included between the one material and the other material.

If the first compositionally graded layer 170, the second compositionally graded layer 270, and the third compositionally graded layer 370 contact each first semiconductor layer 110, 210, and 310 on which each corresponding light-emitting cell 100,200, and 300 is arranged, the first compositionally graded layer 170, the second compositionally graded layer 270, and the third compositionally graded layer 370 may be doped with the same type (p-type or n-type) as the corresponding first semiconductor layers 110, 210, and 310. For example, if the first semiconductor layer 110 is arranged on the first compositionally graded layer 170, the first compositionally graded layer 170 may also be doped with the same type as the first semiconductor layer 110. When the second semiconductor layer 210 is arranged on the second compositionally graded layer 270, the second compositionally graded layer 270 may also be doped with the same type as the second semiconductor layer 210. When the third semiconductor layer 310 is arranged on the third compositionally graded layer 370, the third compositionally graded layer 370 may also be doped with the same type as the third semiconductor layer 210.

A first light-emitting cell 100 may include a first semiconductor layer 110, an active layer 130, and a second semiconductor layer 150. A second light-emitting cell 200 may include a second semiconductor layer 210, an active layer 230, and a second semiconductor layer 250. A third light-emitting cell 300 may include a third semiconductor layer 210, an active layer 330, and a semiconductor layer 350. The layers of one light-emitting cell may be stacked in the above order on the substrate 50 or the corresponding compositionally graded layer. Each lattice constant of the light-emitting cells 100, 200, or 300 may be the same as the lattice constant of the substrate 50 or each corresponding compositionally graded layer 170, 270, or 370 arranged therebelow.

The first semiconductor layers 110, 210, and 310 and the second semiconductor layers 150, 250, and 350 may include a Group II-VI or Group III-V compound semiconductor material. The first semiconductor layers 110, 210, and 310 and the second semiconductor layers 150, 250, and 350 provide electrons and holes to the active layers 130, 230, and 330. For this purpose, the first semiconductor layers 110, 210, and 310 may be doped with an n-type or p-type, and the second semiconductor layers 150, 250, and 350 may be doped with a conductivity type that is electrically opposite to that of the first semiconductor layers 110, 210, and 310. For example, the first semiconductor layers 110, 210, and 310 may be doped with a p-type and the second semiconductor layers 150, 250, and 350 may be doped with an n-type. According to another example, the first semiconductor layers 110, 210, and 310 may be doped with an n-type and the second semiconductor layers 150, 250, and 350 may be doped with a p-type. When the second semiconductor layers 150, 250, 350 are doped into an n-type, for example, silicon (Si) may be used as a dopant, and when the first semiconductor layers 110, 210, 310 are doped into a p-type, for example, zinc (Zn) may be used as a dopant. At this time, the second semiconductor layers 150, 250, and 350 doped with an n-type may provide electrons to the active layers 130, 230, and 330, and the first semiconductor layers 110, 210, and 310 doped with a p-type may provide holes to the active layers 130, 230, and 330.

The active layers 130, 230, and 330 have a quantum well structure in which quantum wells are arranged between barriers. Light may be emitted while electrons and holes provided from the first semiconductor layers 110, 210, and 310 and the second semiconductor layers 150, 250, and 350 are recombined in the quantum well structure in the active layers 130, 230, and 330. A wavelength of light generated in the active layers 130, 230, and 330 may be determined according to a band gap of a material constituting the quantum well in the active layers 130, 230, and 330. The active layers 130, 230, and 330 may have a single quantum well structure, or a multi-quantum well (MQW) structure in which multiple quantum wells and multiple barriers are alternately disposed. Thicknesses of the active layers 130, 230, and 330 or the number of quantum wells in the active layers 130, 230, and 330 may be appropriately selected in consideration of a driving voltage and light emission efficiency of the light-emitting diode 10 to be manufactured.

The active layers 130, 230, and 330 may include a quantum barrier layer and a quantum well layer. For example, the quantum barrier layer may include gallium nitride (GaN), and the quantum well layer may include indium gallium nitride (InₓGa₁₋ₓN (0≤x≤1)). The quantum barrier layer or the quantum well layer may include various materials without being limited to the above example. The active layers 130, 230, and 330 may have a structure in which quantum barrier layers and quantum well layers are alternately stacked N times (where N is a natural number greater than or equal to 1).

The first light-emitting cell 100 may include a 1-1 semiconductor layer 110, a first active layer 130, and a 1-2 semiconductor layer 150, the second light-emitting cell 200 may include a 2-1 semiconductor layer 210, a second active layer 230, and a 2-2 semiconductor layer 250, and the third light-emitting cell 300 may include a 3-1 semiconductor layer 310, a third active layer 330, and a 3-2 semiconductor layer 350. The 1-1 semiconductor layer 110, the 2-1 semiconductor layer 210, and the 3-1 semiconductor layer 310 may correspond to the first semiconductor layers 110, 210, and 310 described above, and the 1-2 semiconductor layer 150, the 2-2 semiconductor layer 250, and the 3-2 semiconductor layer 350 may correspond to the second semiconductor layers 150, 250, and 350 described above. The first active layer 130, and the second active layer 230, and the third active layer 330 may emit light of different colors, respectively. A first color light emitted by the first active layer 130 may exit from the light-emitting diode 10 through the second light-emitting cell 200 and third light-emitting cell 300, and second color light may exit from the light-emitting diode 10 through the third light-emitting cell 300. For example, the first active layer 130 may emit red light, the second active layer 230 may emit green light, and the third active layer 330 may emit blue light. At this time, the first color light may be red light, the second color light may be green light, and the third color light may be blue light. However, embodiments are not limited thereto, and the first to third active layers 130, 230, and 330 may emit light of different colors. For example, a wavelength of light emitted from the first active layer 130 may be greater than a wavelength of light emitted from the second active layer 230, and a wavelength of light emitted from the second active layer 230 may be greater than a wavelength of light emitted from the third active layer 330. Because only one light-emitting cell from among the first to third light-emitting cells 100, 200, and 300 may selectively emit light, when a wavelength of light emitted by the first active layer 130 is less than a wavelength of light emitted by the second active layer 230, the light emitted from the first active layer 130 may activate the second active layer 230 while passing through the light-emitting diode 10, and thus, the first light-emitting cell 100 and second light-emitting cell 200 may simultaneously emit light. Similarly, when a wavelength of light emitted by the second active layer 230 is less than a wavelength of light emitted by the third active layer 330, the light emitted from the second active layer 230 may activate the third active layer 330 while passing through the light-emitting diode 10, and thus, the second light-emitting cell 200 and third light-emitting cell 300 may simultaneously emit light.

The 1-1 semiconductor layer 110 and the 1-2 semiconductor layer 150 may include InₓGa₁₋ₓN (0≤x≤1), and AlₚGa_{q}In_{1-p-q}P (0≤p≤1, 0≤q≤1 and 0≤p+q≤1), etc., the 2-1 semiconductor layer 210 and the 2-2 semiconductor layer 250 may include In_{y}Ga_{1-y}N (0≤y≤1), etc., and the 3-1 semiconductor layer 310 and the 3-2 semiconductor layer 350 may include In_{z}Ga_{1-z}N (0≤z≤1), etc.

When the light-emitting diode 10 according to an example embodiment includes one of the first compositionally graded layer 170, the second compositionally graded layer 270, and the third compositionally graded layer 370, each cross-sectional area of the light-emitting cell, seen from the top of the light-emitting cell arranged on each corresponding compositionally graded layer may be less than a cross-sectional area of the corresponding compositionally graded layer, and each cross-section of the light-emitting cell may be included in the cross-section of the corresponding compositionally graded layer. For example, a cross-sectional area of the second light-emitting cell 200 may be less than a cross-sectional area of the second compositionally graded layer 270, and the cross-section of the second light-emitting cell 200 may be included in the cross-section of the second compositionally graded layer 270. Also, a width of the first light-emitting cell 100 may be greater than a width of the second light-emitting cell 200, and a width of the second light-emitting cell 200 may be greater than a width of the third light-emitting cell 300. The light-emitting diode 10 may have a shape in which the width is reduced according to the thickness.

Each tunnel junction 180 and 280 may electrically connect upper side and lower side of each tunnel junction 180 and 280. A tunnel junction may include at least one semiconductor layer doped more strongly than a first semiconductor layer or a second semiconductor layer of a light-emitting cell to which the tunnel junction are in contact. For example, the tunnel junction 180 may include at least one semiconductor layer doped more strongly than the 1-2 semiconductor layer 150, the tunnel junction 280 may include at least one semiconductor layer doped more strongly than the 2-2 semiconductor layer 250. For example, each tunnel junction 180 and 280 may have a double-layer structure including a strongly p-type doped (p++) semiconductor layer and a strongly n-type doped (n++) semiconductor layer. For example, when a tunnel junction is arranged on a second semiconductor layer of one light-emitting cell and the second semiconductor layer is doped with a p-type, the tunnel junction includes a strongly p-type doped(p++) semiconductor layer and a strongly n-type doped(n++) semiconductor layer, the strongly p-type doped (p++) semiconductor layer is arranged adjacent to the second semiconductor layer, and the strongly n-type doped (n++) semiconductor layer of the tunnel junction is arranged on the p++ semiconductor layer. Further, a first semiconductor layer and/or a compositionally graded layer of another light-emitting cell on the n++ semiconductor layer may be doped to an n-type. A tunnel junction arranged on the second semiconductor layer doped with a p-type may include sequentially arranged a p++ semiconductor layer and an n++ semiconductor layer to form a depletion region, and accordingly, electrons and holes may be transported to up and down the tunnel junction. Therefore, each tunnel junction 180 and 280 may electrically connect an upper side and a lower side of each tunnel junction 180 and 280. In addition, each tunnel junction 180 and 280 may increase light extraction efficiency of the light-emitting diode 10 by inducing lateral current spreading. For example, a nitrogen-based material doped with a p-type has a higher resistance on the scale of about 10³ than that of a nitrogen-based material doped with an n-type. Accordingly, in the case of a vertical electrode structure having a p-electrode on a nitrogen-based material doped with a p-type and an n-electrode on a nitrogen-based material doped with an n-type, a current tends to flow through a nitrogen-based material doped with an n-type having a low resistance, and thus, a lateral current spreading is reduced. Due to reduced lateral current spreading, the electrons are injected only to portions of an active layer, and only the portions of the active layer emits light, and thus, light extracting efficiency may be reduced. When the tunnel junction is arranged on a nitrogen-based material doped with a p-type, electrons passing through the tunnel junction are spread and injected into the tunnel junction, and accordingly, areas of the active layer to which electrons are injected may increase. That is, the light extraction efficiency of each light-emitting cell may be increased by each tunnel junction 180 and 280, and as a result, the light extraction efficiency of the light-emitting diode 10 may be increased.

When the first electrode 410 and the second electrode 420 are connected to respective electrode pads 501 and 502 of a driving layer, the first tunnel junction 180 may be arranged on the first light-emitting cell 100 in contact with the first light-emitting cell 100 to position the first light-emitting cell 100 in an electrically closed circuit. The first tunnel junction 180 may cause lateral current spreading in the first light-emitting cell 100 as well as electrical connection, and thus, may increase the light extraction efficiency of the first light-emitting cell 100. Also, when the second electrode 420 and the third electrode 430 are connected to respective electrode pads 501 and 502 of a drive layer, the second tunnel junction 280 may be arranged on the second light-emitting cell 200 in contact with the second light-emitting cell 200 to position the second light-emitting cell 200 in an electrically closed circuit. The second tunnel junction 280 may cause lateral current spreading in the second light-emitting cell 200 as well as electrical connection, and thus, may increase the light extraction efficiency of the second light-emitting cell 200. When the third electrode 430 and the fourth electrode 440 are connected, the third light-emitting cell 300 is located in an electrically closed circuit without a tunnel junction. The third light-emitting cell 300 may not need a tunnel junction, but is not limited thereto, and the light extraction efficiency may be increased by arranging a third tunnel junction on the third light-emitting cell 300.

A distributed Bragg reflector (DBR) layer may reflect light of a specific wavelength. For example, a first DBR layer 190 may reflect downwardly incident light from among second color light L2 emitted from the second light-emitting cell 200 to be upwardly incident, and may pass through first color light L1 emitted from the first light-emitting cell 100. A second DBR layer 290 may reflect downwardly incident light from among third color light L3 emitted from the third light-emitting cell 300 to be upwardly incident, and may pass through the first color light L1 and the second color light L2. When the second color light L2 emitted from the second light-emitting cell 200 has a wavelength greater than that of the first color light L1 emitted from the first light-emitting cell 100, the light-emitting diode 10 may be configured except for the first DBR layer 190 because the second color light L2 will not optically pump the first light-emitting cell 100. However, in this case, the second light-emitting cell 200 may be optically pumped while the first color light L1 is upwardly incident. According to the structure described above, when a wavelength of the first color light L1 is greater than a wavelength of the second color light L2, the first DBR layer 190 may allow the light-emitting diode 10 according to an example embodiment to selectively emit one color light by upwardly reflecting the second color light L2 incident to downward to the first light-emitting cell 100.

Each of the first and second DBR layers 190 and 290 may have a structure in which two materials having a large difference in refractive index are deposited as multiple layers, and may use an interference phenomenon of light reflected from an interface of each layer. A wavelength of specific light reflected by the first layer 190 or the second DBR layer 290 may be 4N (where, N is a natural number greater than or equal to 1) times larger than the thickness of a single layer of the first layer 190 or second layer 290. When a wavelength of light reflected by the first layer 190 is 400 nm, a thickness of a single layer of the first layer 190 is 100 nm, 25 nm, 6.25 nm, or etc. The specific light may be reflected by the first DBR layer 190 or the second DBR layer 290, and light having a wavelength different from that of the specific light may pass through the first DBR layer 190 or the second DBR layer 290. For example, the first color light L1 may transmit the first DBR layer 190, and the first and second color lights L1 and L2 may transmit the second DBR layer 290.

The light-emitting diode 10 according to an example embodiment may not include an additional DBR layer below the first light-emitting cell 100, but is not limited thereto. However, a third DBR layer may be included under the first light-emitting cell 100. The third DBR layer may reflect the first color light L1 incident to downward. When the light-emitting diode 10 includes the substrate 50 and a material constituting the substrate 50 may absorb the first color light L1, to prevent absorption of the first color light L1, a third DBR layer may be arranged between the substrate 50 and the first light-emitting cell 100. For example, if the substrate 50 includes GaAs, the GaAs may absorb light of a wavelength corresponding to red light, the third DBR layer may further be included.

Among the plurality of light-emitting cells 100, 200, and 300, only a tunnel junction, a DBR layer, and/or a compositionally graded layer may be included between adjacent light-emitting cells, and a bonding layer for attaching the light-emitting cells 100, 200, and 300 may not be included.

The light-emitting diode 10 according to an example embodiment may include a first electrode 410, a second electrode 420, a third electrode 403, and a fourth electrode 440 spaced apart from each other. The first electrode 410 and the second electrode 420, the second electrode 420 and the third electrode 430, the third electrode 430 and the fourth electrode 430 respectively may be adjacently arranged. For example, the first electrode 410 may be arranged on the first compositionally graded layer 170 or may be arranged on the 1-1 semiconductor layer 110. The first electrode 410 may be arranged to be spaced apart from the 1-1 semiconductor layer 110 or arranged in contact with the first electrode 410. Similarly, the second electrode 420 may be arranged on the second compositionally graded layer 270, or on the 2-1 semiconductor layer 210. The third electrode 430 may be arranged on the second compositionally graded layer 370, or on the 3-1 semiconductor layer 310. The first electrode 410 may be arranged on the 1-1 semiconductor layer 110 from which the first active layer 130 and the 1-2 semiconductor layer 150 are partially removed, spaced apart from the first active layer 130 and the 1-2 semiconductor layer 150. In particular, when the first compositionally graded layer 170 is not arranged, the first electrode 410 may be arranged on the 1-1 semiconductor layer 110 as described above. This arrangement may be equally applied to the second electrode 420 and the third electrode 430. The fourth electrode 440 may be arranged on the 3-2 semiconductor layer 350 of the third light-emitting cell 300. When the third tunnel junction is provided on the 3-2 semiconductor layer 350, the fourth electrode 440 may be arranged on the third tunnel junction. As described above, the first electrode 410, the second electrode 420, the third electrode 430 and/or the fourth electrode 440 are not arranged in separate openings formed by partially removing insides of the first light-emitting cell 100, the second light-emitting cell 200, and the third light-emitting cell 300, but may be arranged outside the first light-emitting cell 100, the second light-emitting cell 200, and the third light-emitting cell 300. However, embodiments are not limited thereto, and the first electrode 410, the second electrode 420, the third electrode 430 and/or the fourth electrode 440 may be arranged inside openings formed inside the first light-emitting cell 100, the second light-emitting cell 200, and the third light-emitting cell 300.

The light-emitting diode 10 according to an example embodiment may selectively emit one color light by connecting a pair of adjacent electrodes from among the first to fourth electrodes 410, 420, 430, and 440. For example, when the first electrode 410 and the second electrode 420 are electrically connected to a driving layer, the first light-emitting cell 100 may emit first color light, when the second electrode 420 and the third electrode 430 are electrically connected to the driving layer, the second light-emitting cell 200 may emit second color light, and when the third electrode 430 and the fourth electrode 440 are electrically connected to the driving layer, the third light-emitting cell 300 may emit third color light. For example, the fact that the first electrode 410 and the second electrode 420 are electrically connected to a driving layer may denote that the first electrode 410, the second electrode 420, and the driving layer are in an electrically closed circuit, and also, may denote that the first light-emitting cell 100 between the first electrode 410 and the second electrode 420 is also located in an electrically closed circuit.

Referring to FIG. 2, according to an example embodiment, the first electrode 410 may be arranged in a ring shape on the first compositionally graded layer 170, and according to another example embodiment, the first electrode 410 may be arranged in a ring shape on the 1-1 semiconductor layer 110. Similarly, the second electrode 420 may also be arranged in a ring shape on the second compositionally graded layer 270 or the 2-1 semiconductor layer 210, and the third electrode 430 may also be arranged in a ring shape on the third compositionally graded layer 370 or the 3-1 semiconductor layer 310. However, the shape of the first electrode 410, the second electrode 420, or the third electrode 430 is not limited to the ring shape, and any shape that is topologically identical to a torus having one hole may be possible. In addition, a shape in which a portion of an arc is removed from a ring other than a closed ring shape, that is, an electrode shape in which a cross-section is an arc may also be possible. The fourth electrode 440 may be arranged in a ring shape, or a cross section of the fourth electrode 440 may have a circular shape, an elliptical shape, or a polygonal shape, etc.

According to an example embodiment, the shape of the first electrode 410, the second electrode 420, the third electrode 430, and/or the fourth electrode 440 may have a rotational symmetry with respect to a central axis of the light-emitting diode 10. At this time, the central axis may be a straight line connected to the centers of the first light-emitting cell 100, the second light-emitting cell 200, and the third light-emitting cell 300. In the cross section of FIG. 2, a straight line extending in a direction perpendicular to the cross section in the center of the light-emitting element 10 may be the central axis.

Referring to FIGS. 1 and 2, according to the light-emitting diode 10, the first compositionally graded layer 170 may be arranged on the substrate 50, and the first compositionally graded layer 170 may gradually reduce a lattice constant difference between the substrate 50 and the first light-emitting cell 100. The first light-emitting cell 100 may be arranged on the first compositionally graded layer 170, and first color light L1 emitted from the first light-emitting cell 100 may be red light. A first tunnel junction 180 may be arranged on the first light-emitting cell 100, and when the first electrode 410 and the second electrode 420 are electrically connected to the respective electrode pads 501 and 502 of a driving layer, the first tunnel junction 180 may electrically connect an upper layer and a lower layer of the first tunnel junction 180 so that the first light-emitting cell 100 is included in an electrically closed circuit, and may increase light extraction efficiency by causing lateral current spreading. The first DBR layer 190 may be arranged on the first tunnel junction 180, and the first DBR layer 190 may pass through the first color light L1 and reflect second color light L2. The second compositionally graded layer 270 may be arranged on the first DBR layer 190, and the second compositionally graded layer 270 may gradually reduce a lattice constant difference between the first DBR layer 190 and the second light-emitting cell 200. The second light-emitting cell 200 may be arranged on the second compositionally graded layer 270, and second color light L2 emitted from the second light-emitting cell 200 may be green light. The second tunnel junction 280 may be arranged on the second light-emitting cell 200, and when the second electrode 420 and the third electrode 430 are electrically connected to the respective electrode pads 501 and 502 of the driving layer, the second tunnel junction 280 may electrically connect an upper layer and a lower layer of the second tunnel junction 280 so that the second light-emitting cell 200 is included in an electrically closed circuit, and may increase light extraction efficiency by causing lateral current spreading. The second DBR layer 290 may be arranged on the second tunnel junction 280, and the second DBR layer 290 may pass through the first color light L1 and the second color light L2 and reflect third color light L3. The third compositionally graded layer 370 may be arranged on the second DBR layer 290, and the third compositionally graded layer 370 may gradually reduce a lattice constant difference between the second DBR layer 290 and the third light-emitting cell 300. The third light-emitting cell 300 may be arranged on the third compositionally graded layer 370, and the third color light L3 emitted from the third light-emitting cell 300 may be blue light. Also, the first electrode 410 may be arranged in contact with the first compositionally graded layer 170, the second electrode 420 may be arranged in contact with the second compositionally graded layer 270, and the third electrode 430 may be arranged in contact with the third compositionally graded layer 370, and the fourth electrode 440 may be arranged on the third light-emitting cell 300.

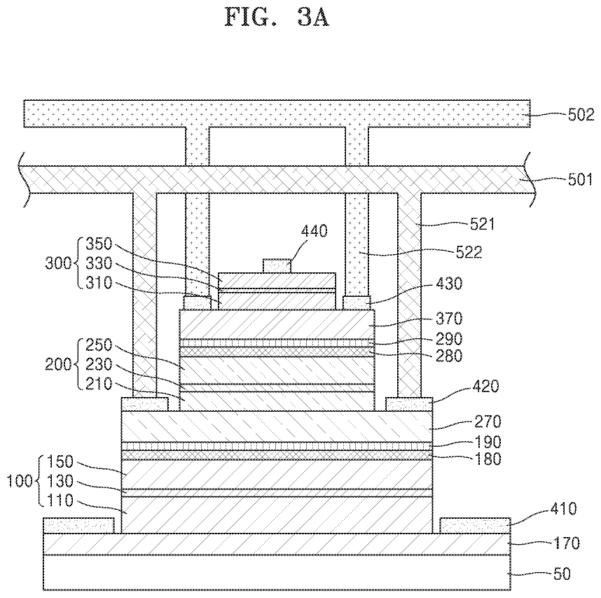

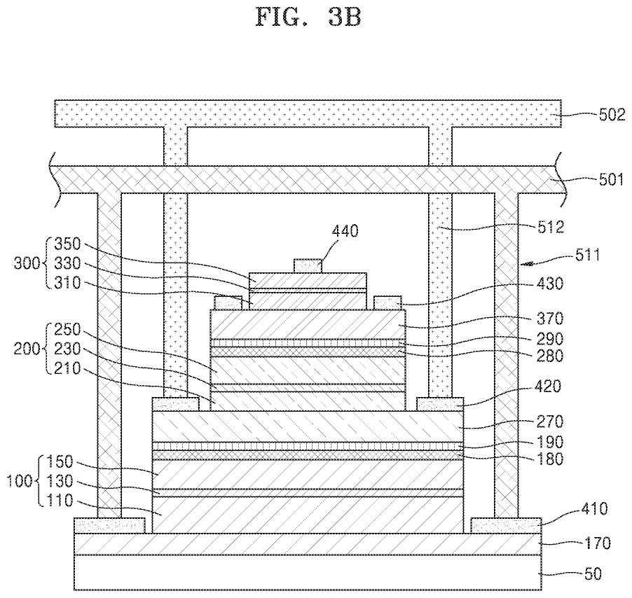

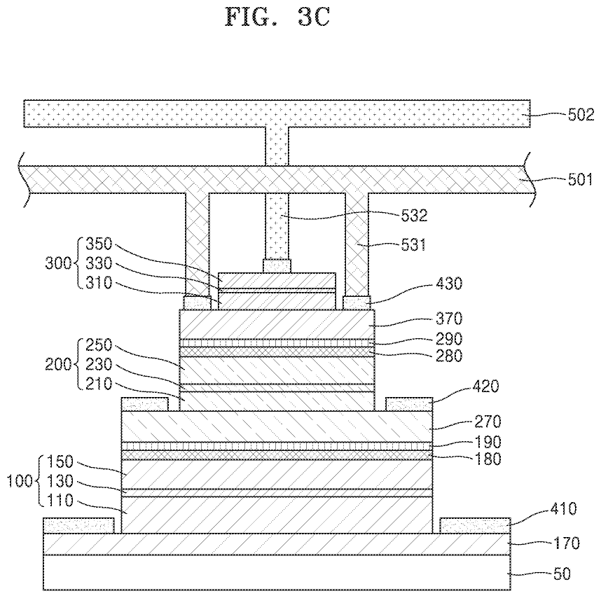

FIG. 3A illustrates a connection between the second electrode 420 and third electrode 430 of the light-emitting diode 10 according to an example embodiment, and electrode pads 501 and 502 of a driving layer, FIG. 3B illustrates a connection between the first electrode 410 and second electrode 420 of the light-emitting diode 10 according to an example embodiment and electrode pads 501 and 502 of the driving layer, and FIG. 3C illustrates a connection between the third and fourth electrodes 430 of the light-emitting diode 10 according to an example embodiment and electrode pads 501 and 502 of the driving layer 500.

Referring to FIG. 3A, the second electrode 420 and the third electrode 430 are connected to the electrode pads 501 and 502 through protrusions 521 and 522 of the driving layer, respectively, and thus, may receive an electrical signal via a transistor located in the driving layer. The first electrode 410 and the fourth electrode 440 may not be electrically connected to the electrode pads 501 and 502. The second light-emitting cell 200 may be located in an electrically closed circuit, and when a current flows through the circuit, the second color light L2 may be emitted from the second active layer 230 of the second light-emitting cell 200. When the second color light L2 is incident on the top, it may pass through the second DBR layer 290, and when the second color light L2 is incident on the bottom, the second color light L2 may be reflected upward by the first DBR layer 190.

Each of the electrode pads 501 and 502 may be spaced apart from each other, and the protrusions 521 and 522 protruding from each of the electrode pads 501 and 502 may be spaced apart from each other. The two electrode pads 501 and 502 may be charged with different poles.

FIG. 3A shows the connection between the second electrode 420 and the third electrode 430. The first electrode 410 and the second electrode 420 may be connected in the same way to emit first color light L1, or the third electrode 430 and the fourth electrode 440 may be connected in the same way to emit third color light L3. Referring to FIG. 3B, the first electrode 410 and the second electrode 420 are connected to the electrode pads 501 and 502 through the protrusions 511 and 512 of the driving layer, respectively, and thus, may receive an electrical signal via a transistor located in the driving layer. In this case, the third electrode 430 and the fourth electrode 440 may not be connected to the electrode pads 501 and 502. The first light-emitting cell 100 may be located in an electrically closed circuit, and when a current flows through the closed circuit, first color light L1 may be emitted from the first active layer 130 of the first light-emitting cell 100. If first color light L1 is incident upward, it may pass through the first DBR layer 190 and the second DBR layer 290. Referring to FIG. 3C, the third electrode 430 and the fourth electrode 440 are connected to the electrode pads 501 and 502 through the protrusions 531 and 532 of the driving layer, respectively, and thus, may receive an electrical signal via a transistor located in the driving layer. In this case, the first electrode 410 and the second electrode 420 may not be connected to the electrode pads 501 and 502. The third light-emitting cell 300 may be located in an electrically closed circuit, and when a current flows through the closed circuit, third color light L3 may be emitted from the third active layer 330 of the third light-emitting cell 300. L3 may be incident upward and exit from a light-emitting diode, and if incident downward, may be reflected upward by the second DBR layer 290. According to a connection between two adjacent electrodes among the four electrodes 410, 420, 430, and 440 and the electrode pads 501 and 502, the light-emitting diode may selectively emit one of first color light L1, second color light L2, or third color light L3.

Two adjacent electrodes from among the first to fourth electrodes 410, 420, 430, and 440 may be connected to the electrode pads 501 and 502 of the driving layer. For example, the first electrode 410 and the second electrode 420 may be connected to the respective electrode pads 501 and 502, the second electrode 420 and the third electrode 430 may be connected to the respective electrode pads 501 and 502, or the third electrode 430 and the fourth electrode 440 may be connected to the respective electrode pads 501 and 502, respectively. In this case, electrodes other than the two adjacent electrodes may not be connected to the electrode pads 501 and 502 of the driving layer. In addition, two non-adjacent electrodes may not be connected to the respective electrode pads 501 and 502. For example, it may be preferable that the first electrode 410 and the third electrode 430 are not connected to the respective electrode pads 501 and 502. This is because, when the first electrode 410 and the third electrode 430 are connected to the respective electrode pads 501 and 502, first color light L1 and second color light L2 may be simultaneously emitted.

Two adjacent electrodes of the first to fourth electrodes 410, 420, 430, and 440 and the electrode pads 501 and 502 of the driving layer may be attached through a method, such as soldering, anisotropic conduction film (ACF), and conducting wires connecting the electrodes. For example, in the case of soldering, the light-emitting diode 10 and the driving layer may be electrically connected to each other by applying heat to a solder paste previously patterned on two adjacent electrodes among the first to fourth electrodes 410, 420, 430 and 440, and the corresponding protrusions of electrode pads 501 and 502 per one sub-pixel. For example, in order to connect the second and third electrodes 420 and 430 to the driving layer, the ACF uses fine conductive beads, and when heat and pressure are applied between the light-emitting diode 10 and the driving layer, the beads between the second electrode 420 and third electrode 430 and the corresponding protrusions 521 and 522 of the electrode pads 501 and 502 are crushed, and thus, the second electrode 420 and third electrodes 430 and the electrode pads 501 and 502 may be attached and electrically connected. In this case, because protrusions corresponding to the first and fourth electrodes 410 and 440 are not provided in a region where the light-emitting diode 10 is arranged, beads between the first and fourth electrodes 410 and 440 and the electrode pads 501 and 502 are not crushed and attached and may not be electrically connected. For example, in order for the light-emitting diode 10 arranged in one region of the driving layer 500 to emit second color light L2, when the second electrode 420 and the third electrode 430 are to be electrically connected to the driving layer, beads between the protrusions 521 and 522 protruding from the electrode pads 501 and 502 and the second and third electrodes 420 and 430 to be attached thereto may be attached by being crushed with heat and pressure. At this time, in one region of the driving layer, protrusions protruding corresponding to the first electrode 410 and the fourth electrode 440 are not included, and thus, even when heat and pressure are applied to the region, the first electrode 410 and the fourth electrode 440 may not be electrically connected to the driving layer.

The driving layer may include a plurality of transistors electrically connected to the plurality of light-emitting diodes 10, and may drive the plurality of light-emitting diodes 10. The driving layer may include first to third regions that do not overlap each other. In the first region, each of the protrusions 511 and 512 may protrude from the respective electrode pads 501 and 502 to be electrically connected to the first electrode 410 and the second electrode 420 of the light-emitting diode 10, in the second region, each of the protrusions 521 and 522 may protrude from the respective electrode pads 501 and 502 to be electrically connected to the second electrode 420 and the third electrode 430 of the light-emitting diode 10, and in the third region, each of the protrusions 531 and 532 may protrude from each of the electrode pads 501 and 502 to be electrically connected to the third electrode 430 and the fourth electrode 440 of the light-emitting diode 10. A detailed description thereof will be given below.

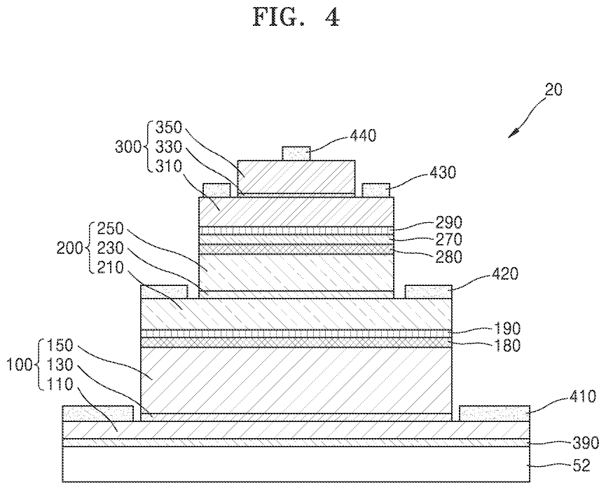

FIG. 4 is a cross-sectional view seen from a side of a light-emitting diode 20 according to another example embodiment.

Referring to FIG. 4, the light-emitting diode 20 according to an embodiment may include: a first substrate 52, a first light-emitting cell 100, a first tunnel junction 180 and a first DBR layer 190 sequentially arranged on the first light-emitting cell 100, a second light-emitting cell 200; a second tunnel junction 280 and a second DBR layer 290 sequentially arranged on the second light-emitting cell 200, and a third light-emitting cell 300. In addition, the light-emitting diode 20 according to an example embodiment may include a second compositionally graded layer 270 between the second light-emitting cell 200 and the third light-emitting cell 300, and a third DBR layer 390 may further be included under the first light-emitting cell 100. The light-emitting diode 20 according to an example embodiment may include four electrodes, for example, a first electrode 410, a second electrode 420, a third electrode 430, and a fourth electrode 440. The first electrode 410, the second electrode 420, and the third electrode 430 may contact the first light-emitting cell 100, the second light-emitting cell 200, and the third light-emitting cell 300, respectively, and the fourth electrode 440 may be spaced apart from the third electrode 430 and may be in contact the third light-emitting cell 300. A current may selectively flow through one of the first light-emitting cell 100, the second light-emitting cell 200, or the third light-emitting cell 300 by connecting adjacent two electrodes among the first to fourth electrodes 410, 420, 430, and 440, and accordingly, light may be emitted from active layers 130, 230, or 330 of the corresponding light-emitting cells.

Each lattice constant of the first substrate 52 of the light-emitting diode 20 and the first light-emitting cell 100 according to an example embodiment may be substantially the same, and the first compositionally graded layer 170 may not be included therebetween. For example, when the first substrate 52 includes GaAs and the first light-emitting cell 100 includes AlₚGa_{q}In_{1-p-q}P (0≤p≤1, 0≤q≤1, 0≤p+q≤1), the lattice constant of the first light-emitting cell 100 and that of GaAs may be the same by controlling p and q of the first light-emitting cell 100, and in this case, the first light-emitting cell 100 may be grown without the need for the first compositionally graded layer 170. When first color light L1 emitted from the first light-emitting cell 100 is red light, the red light may be absorbed by GaAs, thus, the light-emitting diode 20 may further include a third DBR layer 390 under the first light-emitting cell 100. In this case, the third DBR layer 390 may be configured to reflect the first color light L1.

The light-emitting diode 20 according to an example embodiment may be a light-emitting diode in which a first element including the first light-emitting cell 100 and a second element including the second light-emitting cell 200 and the third light-emitting cell 300 are coupled. For example, the light-emitting diode 20 according to an example embodiment may be a light-emitting diode in which the first element and the second element respectively grown on heterogeneous substrates, not a single grown light-emitting diode on a single substrate, are coupled. In this case, the second compositionally graded layer 270 may not be included between the first light-emitting cell 100 and the second light-emitting cell 200. When the second light-emitting cell 200 and the third light-emitting cell 300 include the same element with different composition ratios, the elements may be included together as one element.

However, the configurations of the first element and the second element are not limited thereto, that is, the first element may include the first light-emitting cell 100 and the second light-emitting cell 200, and the second element may include the third light-emitting cell 300. In this case, the second compositionally graded layer 270 may be included between the first light-emitting cell 100 and the second light-emitting cell 200, and the third compositionally graded layer 370 may not be included between the second light-emitting cell 200 and the third light-emitting cell 300. When the first light-emitting cell 100 and the second light-emitting cell 200 include the same element with different composition ratios, the elements may be included together as one element.

When the light-emitting diode 20 according to an example embodiment is a light-emitting diode in which a first element including the first light-emitting cell 100 and a second element including the second light-emitting cell 200 and the third light-emitting cell 300 are coupled, the light-emitting diode 20 may include the second compositionally graded layer 270 under the third light-emitting cell 300. This is because, when the second element is grown, the second light-emitting cell 200 is grown on the third light-emitting cell 300, and the second element is turned over to be coupled to the first element. However, embodiments are not limited thereto, and when the third light-emitting cell 300 is grown on the second light-emitting cell 200 in the second element, the light-emitting diode 20 may include a third compositionally graded layer 370 under the third light-emitting cell 300. In this case, a second substrate of the second element and the second compositionally graded layer 270 on the second substrate may be removed before the first element and the second element are coupled. Also, in a light-emitting diode according to another example embodiment, when the first element includes the first light-emitting cell 100 and the second light-emitting cell 200, and the second element includes the third light-emitting cell 300, the second compositionally graded layer 270 may be included under the second light-emitting cell 200.

The light-emitting diode 20 according to an example embodiment may include a first electrode 410, a second electrode 420, a third electrode 430, and a fourth electrode 440. The first electrode 410 and the second electrode 420, the second electrode 420 and the third electrode 430, and the third electrode 430 and the fourth electrode 440 may be arranged adjacent to each other, respectively. Each of the first to third electrodes 410, 420, and 430 may contact the first light-emitting cell 100, the second light-emitting cell 200, and the third light-emitting cell 300, respectively. In more detail, in order to arrange the first electrode 410, the first active layer 130 and the 1-2 semiconductor layer 150 may be partially removed, and the first electrode 410 may be arranged on the 1-1 semiconductor layer 110 to be spaced apart from the first active layer 130 and the 1-2 semiconductor layer 150. An etching process may be used to partially remove the first active layer 130 and the 1-2 semiconductor layer 150. However, embodiments are not limited thereto, and the first electrode 410 may be arranged by being spaced apart from the first active layer 130 and the 1-2 semiconductor layer 150 through various processes other than the etching process, and alternatively, when the first light-emitting cell 100 is grown, the first active layer 130 and the 1-2 semiconductor layer 150 may be grown except for a position where the first electrode 410 is to be arranged in advance. Similarly, the second electrode 420 may also be arranged on the 2-1 semiconductor layer 210 by being spaced apart from the second active layer 230 and the 2-2 semiconductor layer 250, and the third electrode 430 may also be arranged on the 3-1 semiconductor layer 310 by being spaced apart from the third active layer 330 and the 3-2 semiconductor layer 350. The fourth electrode 440 may be arranged on the 3-2 semiconductor layer 350 of the third light-emitting cell 300. As described above, the first electrode 410, the second electrode 420, the third electrode 430 and/or the fourth electrode 440 are not arranged in separate openings formed by partially removing insides of the first light-emitting cell 100, the second light-emitting cell 200, and the third light-emitting cell 300, but may be arranged outside the first light-emitting cell 100, the second light-emitting cell 200, and the third light-emitting cell 300. However, embodiments are not limited thereto, and the first electrode 410, the second electrode 420, the third electrode 430 and/or the fourth electrode 440 may be arranged inside openings formed inside the first light-emitting cell 100, the second light-emitting cell 200, and the third light-emitting cell 300.

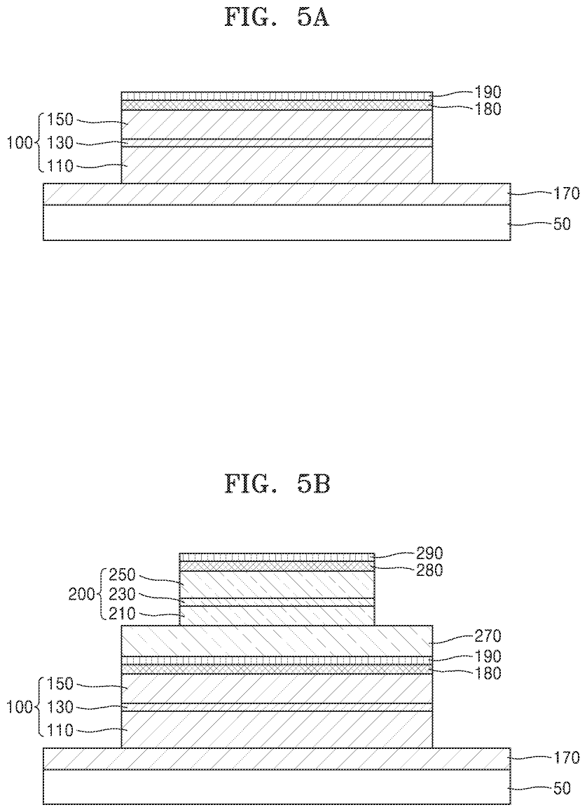

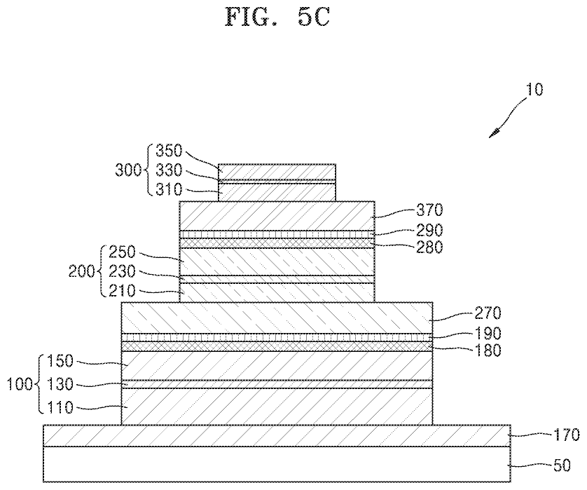

FIGS. 5A to 5C illustrate a method of manufacturing the monolithic growth light-emitting diode 10 on a single substrate 50 according to an example embodiment.

Referring to FIG. 5A, the substrate 50 may be prepared, and a first compositionally graded layer 170 may be grown on the single substrate 50. For example, if the lattice constant of the single substrate 50 is a nm and the lattice constant of the first light-emitting cell 100 to be grown on the first compositionally graded layer 170 is b nm, the first compositionally graded layer 170 may have gradually changing lattice constant between a nm and b nm according to the thickness from below. As the thickness increases, the lattice constant may be gradually changed (increased or decreased) from a nm to b nm. In this case, the compositionally graded layer may be considered as a structure in which single layers are stacked, each having a gradually changing composition for epitaxial connection of two layers having different lattice constants.

The first light-emitting cell 100 including a 1-1 semiconductor layer 110, a first active layer 130, and a 1-2 semiconductor layer 150 may be grown on the first compositionally graded layer 170. The 1-1 semiconductor layer 110, the first active layer 130, and the 1-2 semiconductor layer 150 may be sequentially grown. A cross-sectional area of the first light-emitting cell 100 to be grown may be less than a cross-sectional area of the first compositionally graded layer 170, and a cross section of the first light-emitting cell 100 may be included inside the cross-section of the first compositionally graded layer 170.

A first tunnel junction 180 may be stacked on the first light-emitting cell 100, and the first tunnel junction 180 may include at least one semiconductor layer doped more strongly than the 1-1 semiconductor layer 110 or the 1-2 semiconductor layer 150.

A first DBR layer 190 may be stacked on the first tunnel junction 180. The first DBR layer 190 may pass first color light L1 emitted from the first light-emitting cell 100 and reflect second color light L2 emitted from the second light-emitting cell 200.

Referring to FIG. 5B, a second compositionally graded layer 270 may be grown on the first DBR layer 190. The process of FIG. 5B corresponds to FIG. 5A, and only the first light-emitting cell 100 is changed to the second light-emitting cell 200, and thus, a detailed description thereof will be omitted.

Referring to FIG. 5C, a third compositionally graded layer 370 may be grown on the second DBR layer 290. The process of FIG. 5C corresponds to FIG. 5B, and only the second light-emitting cell 200 is changed to the third light-emitting cell 300, and thus, a detailed description thereof will be omitted. However, a third tunnel junction may or may not be formed on the third light-emitting cell 300.

After the first light-emitting cell 100, the second light-emitting cell 200, and the third light-emitting cell 300 are grown, the first electrode 410, the second electrode 420, the third electrode 430, and the fourth electrode 440 may be formed. The first electrode 410 may be formed in a ring shape on the first compositionally graded layer 170. The first electrode 410 may be formed to be spaced apart from the first active layer 130 and the 1-2 semiconductor layer 150. The first electrode 410 is not limited to being formed on an outer circumference of the first compositionally graded layer 170, but may be formed on the 1-1 semiconductor layer 110 to be spaced apart from the first active layer 130 and the 1-2 semiconductor layer 150. To this end, the location for the first electrode 410 may be generated by partially removing the first active layer 130 and the 1-2 semiconductor layer 150 by using various methods, such as etching, or when the first light-emitting cell 100 is grown, the first active layer 130 and the 1-2 semiconductor layer 150 are grown on the 1-1 semiconductor layer 110 except for a location where the first electrode 410 is to be located. The formation of the second electrode 420 and the third electrode 430 may also correspond to the formation of the first electrode 410. That is, the second electrode 420 may be formed on the second compositionally graded layer 270 or the 2-1 semiconductor layer 210, and the third electrode 430 may be formed on the third compositionally graded layer 370 or the 3-1 semiconductor layer 310. The fourth electrode 440 may be formed on the 3-2 semiconductor layer 350 in a ring shape, or a cross section of the fourth electrode 440 may have a circular shape, an elliptical shape, or a polygonal shape, etc.

Forming of the first electrode 410, the second electrode 420, the third electrode 430, and the fourth electrode 440 is not limited to being formed after all of the first light-emitting cell 100, the second light-emitting cell 200, and the third light-emitting cell 300 are grown. The first electrode 410 may be formed after growth of the first compositionally graded layer 170 or after growth of the first light-emitting cell 100, the second electrode 420 may be formed after growth of the second compositionally graded layer 270 or after growth of the second light-emitting cell 200, the third electrode 430 may be formed after growth of the third compositionally graded layer 370 or after growth of the third light-emitting cell 300, and the fourth electrode 440 may be formed after growth of the third light-emitting cell 300.

When the light-emitting diode 10 is manufactured by using the single growth method described with reference to FIGS. 5A to 5C, the light-emitting diode 10 may be manufactured without an additional bonding process. Accordingly, only a tunnel junction, a DBR layer, and/or a compositionally graded layer may be included between adjacent light-emitting cells among the plurality of light-emitting cells 100, 200, and 300. For example, bonding layers for attaching the first to third light-emitting cells 100, 200, and 300 to each other may not be included.

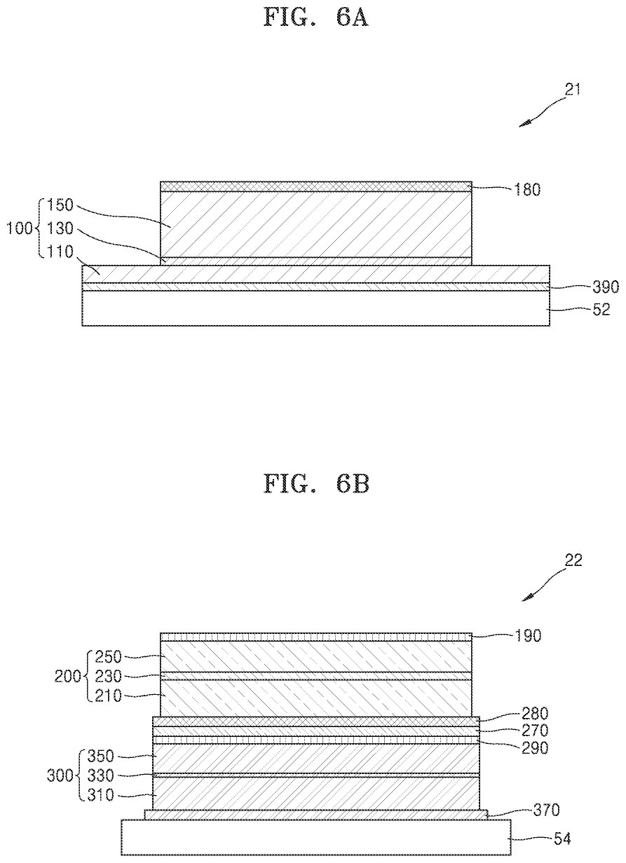

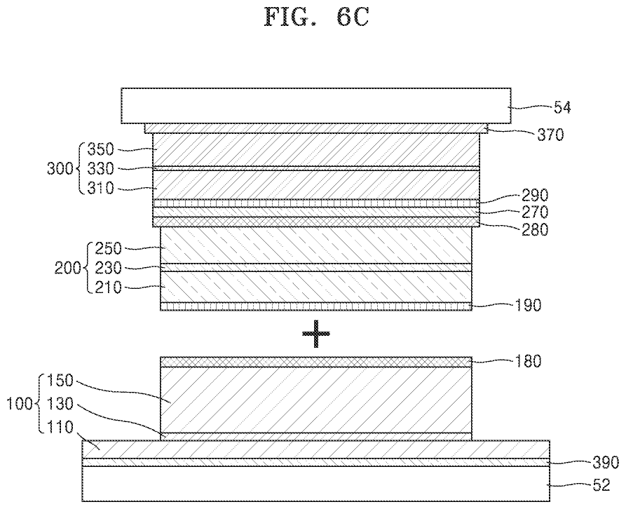

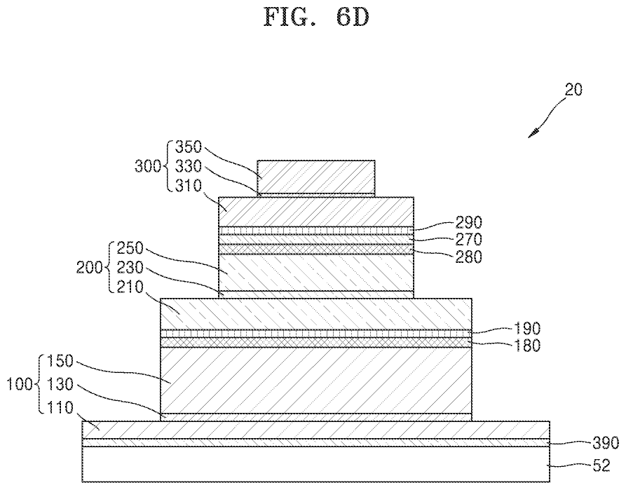

FIGS. 6A to 6D illustrate a method of manufacturing the light-emitting diode 20 by bonding a first element 21 and a second element 22 respectively grown on heterogeneous substrates 52 and 54, according to another example embodiment.

A heterogeneous substrate bonding method of manufacturing a light-emitting diode may include: growing a first element, growing a second element, bonding the first element and the second element, removing a second substrate of the second element, and forming an electrode.

Referring to FIG. 6A, a first substrate 52 may be prepared for growing the first element 21, and a third DBR layer 390 may be arranged on the first substrate 52. The third DBR layer 390 may prevent first color light L1 emitted from the first light-emitting cell 100 from being absorbed by the first substrate 52, by reflecting the first color light L1 upward when the first color light L1 is incident downward. A first light-emitting cell 100 including a 1-1 semiconductor layer 110, a first active layer 130 and a 1-2 semiconductor layer 150 may be grown on the third DBR layer 390. The 1-1 semiconductor layer 110, the first active layer 130, and the 1-2 semiconductor layer 150 may be sequentially grown. The first light-emitting cell 100 may have substantially the same lattice structure as the first substrate 52 and the third DBR layer 390, and may be grown without a first compositionally graded layer 170. However, if necessary, the first compositionally graded layer 170 may be included. The first active layer 130 and the 1-2 semiconductor layer 150 may be grown only on a portion of the 1-1 semiconductor layer 110 excluding the location where the first electrode 410 is to be formed.

A first tunnel junction 180 may be formed on the first light-emitting cell 100, and a first DBR layer 190 may be formed on the first tunnel junction 180. However, only the first tunnel junction 180 may be stacked, and in this case, the first DBR layer 190 may be formed on the second element 22. According to another example, both the first tunnel junction 180 and the first DBR layer 190 may not be formed on the first element 21, but the first DBR layer 190 and the first tunnel junction 180 may be sequentially formed on the second element 22. However, embodiments are not limited thereto, and, for example, the first tunnel junction 180 may be formed on the first light-emitting cell 100 to match the lattice constant with the first light-emitting cell 100.

Referring to FIG. 6B, a second substrate 54 may be prepared for growing the second element 22, and a third compositionally graded layer 370 may be grown on the second substrate 54. A third light-emitting cell 300 including a 3-1 semiconductor layer 310, a third active layer 330, and a 3-2 semiconductor layer 350 is grown on the third compositionally graded layer 370. The 3-2 semiconductor layer 350, the third active layer 330, and the 3-1 semiconductor layer 310 may be sequentially grown. The reason why the growth order of the monolithic growth light-emitting diode 20 is reversed is that, in order to be coupled to the first element 21, the second element 22 is turned over in a direction opposite to a growth direction.

A second compositionally graded layer 270, a second DBR layer 290, and a second tunnel junction 280 may be sequentially formed on the third light-emitting cell 300. The embodiments are not limited thereto, and the second DBR layer 290, the second compositionally graded layer 270, and the second tunnel junction 280 may be sequentially formed. Because the second tunnel junction 280 may have the same lattice constant as the second light-emitting cell 200, the second compositionally graded layer 270 may be formed before the second tunnel junction 280 is formed. The reason why the formation order of the second DBR layer 290 and the second tunnel junction 280 is opposite to that of the single-growth light-emitting diode 10 is the same as described above.

A second light-emitting cell 200 including a 2-1 semiconductor layer 210, a second active layer 230, and a 2-2 semiconductor layer 250 may be grown on the second tunnel junction 280. The 2-2 semiconductor layer 250, the second active layer 230, and the 2-1 semiconductor layer 210 may be sequentially grown.

The first DBR layer 190 may be formed on the second light-emitting cell 200, and the first tunnel junction 180 may be formed on the first DBR layer 190. When the first tunnel junction 180 is formed in the first element 21, only the first DBR layer 190 may be formed on the second element 22, and when the first tunnel junction 180 and the first DBR layer 190 are formed in the first element 21, the formation of the first tunnel junction 180 and the first DBR layer 190 in the second element 22 may not be needed. However, embodiments are not limited thereto, and, for example, the first tunnel junction 180 may be formed on the first light-emitting cell 100 to match the lattice constant with that of the first light-emitting cell 100.

Although the second element 22 described above, in order to be coupled to the first element 21 in a direction opposite to a growth direction, is formed in the order described above, but embodiments are not limited thereto, and, for example, in order to be coupled to the first element 21 in the growth direction, the second element 22 may be formed differently. In this case, the second compositionally graded layer 270, the 2-1 semiconductor layer 210, the second active layer 230, the 2-2 semiconductor layer 250, the second tunnel junction 280, the second DBR layer 290, the third compositionally graded layer 370, the 3-1 semiconductor layer 310, the third active layer 330, and the 3-2 semiconductor layer 350 are sequentially formed on the second substrate 54. At this time, the second substrate 54 of the second element 22 may be removed before the first element 21 and the second element 22 are coupled to each other, and the second compositionally graded layer 270 may be or may not be removed.

Referring to FIG. 6C, the second element 22 may be turned over in a direction opposite to the growth direction to be coupled to the first element 21. After coupling, the second substrate 54 of the second element 22 may be removed, and the third compositionally graded layer 370 may be or may not be removed. The removal process may be performed after the second element 22 is completely grown before coupling.

Referring to FIG. 6D, in order to form the first to third electrodes 410, 420, and 430, each corresponding active layer 130, 230, or 330 and each corresponding second semiconductor 150, 250 or 350 may be partially removed by using various methods, such as, for example, etching. A portion of the first active layer 130 and the 1-2 semiconductor layer 150 may be removed, and the first electrode 410 may be formed on the 1-1 semiconductor layer 110 to be spaced apart from the first active layer 130 and the 1-2 semiconductor layer 150. A portion of the second active layer 230 and the 2-2 semiconductor layer 250 may be removed, and the second electrode 420 may be formed on the 2-1 semiconductor layer 210 to be spaced apart from the second active layer 230 and the 2-2 semiconductor layer 250. A portion of the third active layer 303 and the 3-3 semiconductor layer 350 may be removed, and the third electrode 430 may be formed on the 3-1 semiconductor layer 310 to be spaced apart from the third active layer 330 and the 3-2 semiconductor layer 350. A fourth electrode 440 may be formed on the 3-2 semiconductor layer 350. According to another example, the first active layer 130 and the 1-2 semiconductor layer 150 may be grown on the first light-emitting cell 100 except for a location where the first electrode 410 is to be located during the process of forming the first light-emitting cell 100. In this case, in order to form the first electrode 410, the first light-emitting cell 100 may not require an additional removal process. When the second element 22 is coupled to the first element 21 in the growth direction, the second light-emitting cell 200 and the third light-emitting cell 300 may also be formed so that an additional removal process is not required.

In the light-emitting diode 20 according to another example embodiment, the first element 21 includes the first light-emitting cell 100, and the second element 22 includes the second light-emitting cell 200 and the third light-emitting cell 300, but embodiments are not limited thereto, that is, the first element 21 may include the first light-emitting cell 100 and the second light-emitting cell 200, and the second element 22 may include the third light-emitting cell 300. In this case, in the first element 21, the third DBR layer 390, the 1-1 semiconductor layer 110, the first active layer 130, the 1-2 semiconductor layer 150, the first tunnel junction 180, the first DBR layer 190, the second compositionally graded layer 270, the 2-1 semiconductor layer 210, the second active layer 230, and the 2-2 semiconductor layer 250 may be sequentially formed on the first substrate 52. In the second element 22, the third compositionally graded layer 370, the 3-2 semiconductor layer 350, the third active layer 330, and the 3-1 semiconductor layer 310 are sequentially formed on the second substrate 54. The second element 22 may be coupled to the first element 21 by being turned over in a direction opposite to the growth direction.

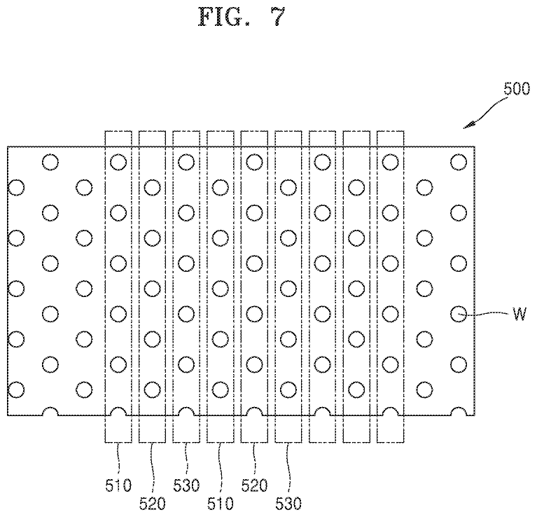

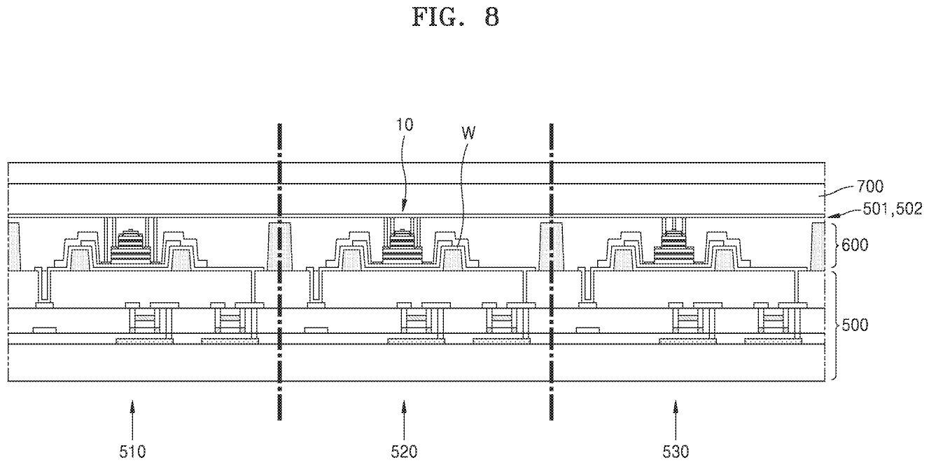

FIG. 7 is a diagram illustrating a cross-section seen from top of a driving layer 500 of a display device including a plurality of wells W, and FIG. 8 illustrates a display device including the light-emitting diodes 10 and 20, according to an example embodiment.

Referring to FIGS. 7 and 8, a display device according to an example embodiment includes a display layer 600 including a plurality of light-emitting diodes, a transistor electrically connected to the plurality of light-emitting diodes, and a driving layer 500 configured to drive the plurality of light-emitting diodes. In this case, the light-emitting diodes may be the light-emitting diodes 10 and/or 20 described with reference to FIGS. 1 to 6D. The driving layer 500 may include a first region 510, a second region 520, and a third region 530 that do not overlap each other, and the first to third regions 510 520, and 530 may include at least one well (W), respectively. The first to third regions 510, 520, and 530 may be alternately arranged according to an order, and may emit light of different colors, respectively. The driving layer 500 may include electrode pads 501 and 502, and although the electrode pads 501 and 502 overlap in a cross-sectional view, they are spaced apart from each other. The light-emitting diodes 10 and/or 20 may be transferred to and fixed on the plurality of wells W of the driving layer 500 of the display device to form pixels. When the light-emitting diode 10 is transferred to the driving layer 500, the light-emitting diode 10 may be electrically connected to a transistor, and the light-emitting diodes 10 and/or 20 may be operated according to a signal of the transistor. For example, the light-emitting diodes 10 and/or 20 located in the well W of the first region 510 may emit light of a first color, the light-emitting diodes 10 and/or 20 located in the well W of the second region 520 may emit light of a second color, and the light-emitting diodes 10 and/or 20 located in the well W of the third region 530 may emit light of a third color.

Each protrusion of the first region 510 may protrude from each of the electrode pads 501 and 502 to be electrically connected to the first electrode 410 and the second electrode 420 of the light-emitting diodes 10 and/or 20, each protrusion of the second region 520 may protrude from each of the electrode pads 501 and 502 to be electrically connected to the second electrode 420 and the third electrode 430 of the light-emitting diodes 10 and/or 20, and each protrusion of the third region 530 may protrude from each of the electrode pads 501 and 502 to be electrically connected to the third electrode 430 and the fourth electrode 440 of the light-emitting diodes 10 and/or 20. Accordingly, the first region 510 may emit only light of a first color, the first region 520 may emit only light of a second color, and the third region 530 may emit only light of a third color. At least one of the light-emitting diodes 10 and/or 20 in the first region 510, at least one of the light-emitting diodes 10 and/or 20 in the second region 520, and at least one of the light-emitting diodes 10 and/or 20 in the third region 530 may form one pixel. The display layer 600 including the light-emitting diodes 10 and 20 may be passivated 700.

As described above, because the first region 510, the second region 520, and the third region 530 respectively may emit light of different colors from each other, a full color display device may be implemented without using a first method in which each of the light-emitting diodes emitting red light (R), green light (G), and blue light (B) is transferred to a corresponding well (W) or a second method in which, after transferring a light-emitting diode emitting blue light (B) to the entire light-emitting diodes, a color conversion layer is used. The first method requires high cost because each R, G, and B light-emitting diodes must be transferred, respectively, and in the second method, when a color conversion layer is used, phosphor of the color conversion layer is deteriorated due to heat, and thus, there is a problem that the lifetime of the display device is reduced, and the quantum dot coating requires high cost. On the other hand, because the display device including the light-emitting diode 10 and/or 20 according to example embodiments do not use the first method or the second method, the manufacturing process time may be more efficiently reduced, and because a color conversion layer is not included, there is no deterioration of a phosphor layer, and thus, there are advantages of extending the lifespan and reducing the cost.

The display device including the light-emitting diodes 10 and/or 20 described with reference to FIGS. 1 to 6D may be used in various electronic devices.

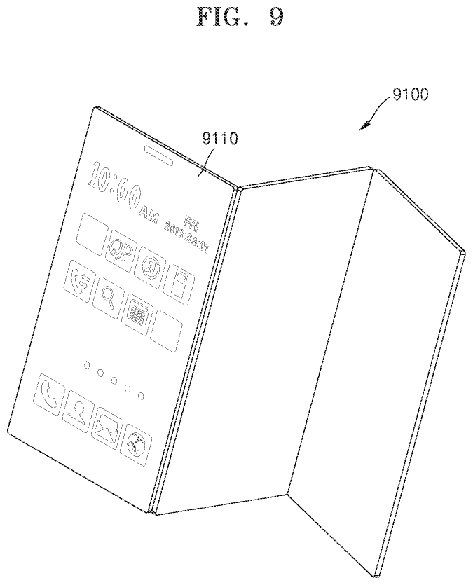

FIG. 9 illustrates an example in which a display device according to an example embodiment is applied to a mobile device 9100. The mobile device 9100 may include a display diode 9110 according to an example embodiment. The display diode 9110 may include the light-emitting diodes 10 and 20 described with reference to FIGS. 1 to 6D. The display diode 9110 may have a foldable structure and, for example, may be applied to a multi-folder display. Here, although it is depicted that the mobile device 9100 is a foldable display, it may be applicable to a general flat panel display.

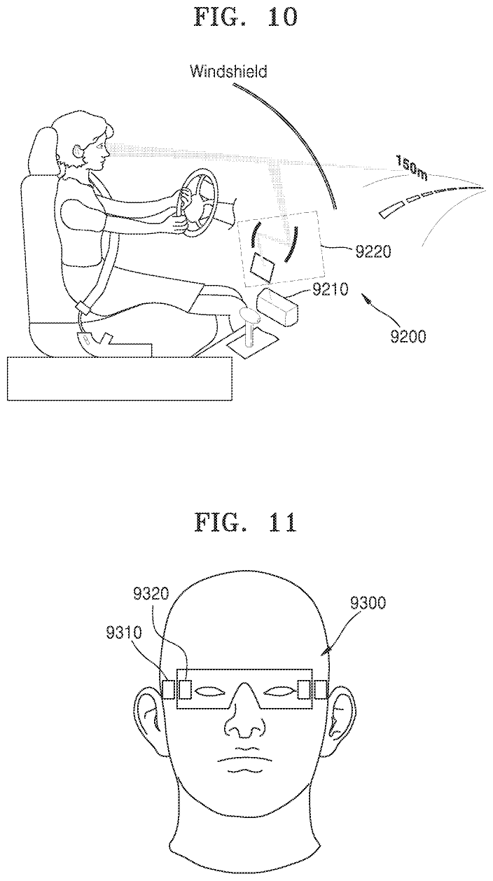

FIG. 10 illustrates an example in which a display device according to an example embodiment is applied to an automobile. The display device may be applied to a head-up display device 9200 for a vehicle. The head-up display device 9200 may include a display device 9210 provided in an area of a vehicle and at least one light path-changing member 9220 configured to convert a path of light so that the driver sees an image generated by the display device 9210.

FIG. 11 illustrates an example in which a display device according to an example embodiment is applied to augmented reality glasses 9300 or virtual reality glasses. The augmented reality glasses 9300 may include a projection system 9310 configured to forms an image and at least one element 9320 configured to guide the image from the projection system 9310 into a user's eye. The projection system 9310 may include the light-emitting diodes 10 and 20 described with reference to FIGS. 1 to 6D.

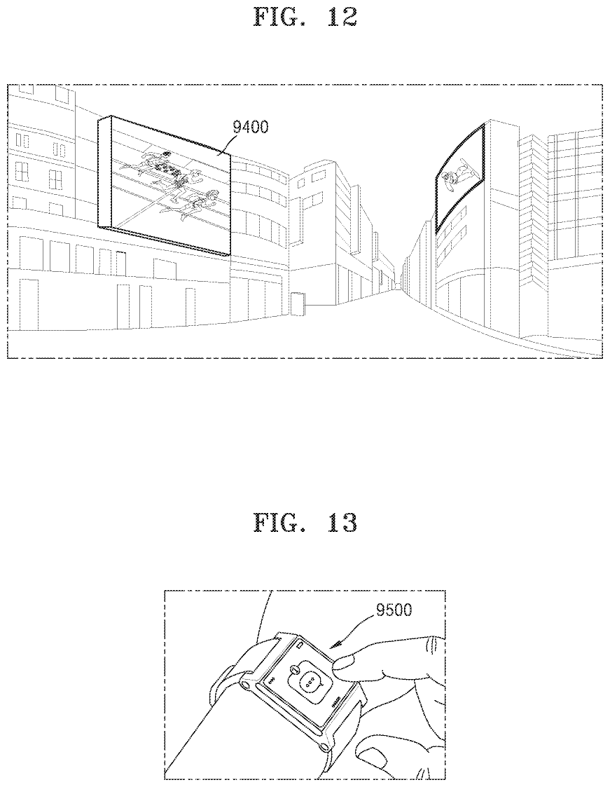

FIG. 12 illustrates an example in which a display device according to an example embodiment is applied to a large-sized signage 9400. The signage 9400 may be used for outdoor advertisement by using a digital information display, and may control advertisement contents and the like through a communication network.

FIG. 13 illustrates an example in which a display device according to an example embodiment is applied to a wearable display 9500. The wearable display 9500 may include the light-emitting diodes 10 and 20 described with reference to FIGS. 1 to 6D.

The display device according to an example embodiment may be applied to an LED TV, a liquid crystal display, a mobile display, a smart watch, an aggregated reality (AR) glass, a VR (virtual reality) glass, a head-up display, or a signage. Besides above, the display device may be applied to various products, such as a rollable TV, a stretchable display, etc.

In the light-emitting diode according to example embodiments, first to third light-emitting cells emitting light of first to third colors respectively may be implemented as a single growth.

The light-emitting diode according to example embodiments may selectively emit light of first to third colors according to electrode connection.

The light-emitting diode according to example embodiments includes a tunnel junction to induce lateral current spreading, and thus, may have high light extraction efficiency.

Because the light-emitting diode according to example embodiments may selectively emit light of first to third colors according to electrode connection, it is possible to reduce the time and cost of transferring each of the light-emitting diodes emitting different light of colors, and a full color may be realized without using a color conversion layer.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A light-emitting diode comprising:
a first-light emitting cell, a second light-emitting cell, and a third light-emitting cell that are sequentially provided in one direction and configured to emit light of different colors from each other;
a first tunnel junction provided between the first light-emitting cell and the second light-emitting cell, the first tunnel junction being configured to electrically connect the first light-emitting cell and the second light-emitting cell and induce lateral current spreading; and
a second tunnel junction provided between the second light-emitting cell and the third light-emitting cell, the second tunnel junction being configured to electrically connect the second light-emitting cell and the third light-emitting cell and induce lateral current spreading.

2. The light-emitting diode of claim 1, further comprising:
a first electrode in contact with the first light-emitting cell;
a second electrode in contact with the second light-emitting cell; and
a third electrode and a fourth electrode spaced apart from each other and in contact with the third light-emitting cell.

3. The light-emitting diode of claim 2, wherein the first electrode, the second electrode, the third electrode, and the fourth electrode are symmetrical with respect to a central axis of the light-emitting diode.

4. The light-emitting diode of claim 2, wherein cross-sectional shapes of the first electrode, the second electrode, and the third electrode are ring-shapes, and
wherein a cross-sectional shape of the fourth electrode is one of a circular shape, an oval shape, a polygonal shape, and a ring shape.

5. The light-emitting diode of claim 2, wherein two adjacent electrodes from among the first electrode, the second electrode, the third electrode, and the fourth electrode are electrically connected to electrode pads of a driving layer based on at least one of soldering, anisotropic conductive film (ACF), or attachment using a conducting wire.

6. The light-emitting diode of claim 2, wherein when the first electrode and the second electrode are electrically connected, the first light-emitting cell is configured to emit light of a first color,
wherein when the second electrode and the third electrode are electrically connected, the second light-emitting cell is configured to emit light of a second color, and
wherein when the third electrode and the fourth electrode are electrically connected, the third light-emitting cell is configured to emit light of a third color.

7. The light-emitting diode of claim 6, wherein the light of the first color is red light, the light of the second color is green light, and the light of the third color is blue light.

8. The light-emitting diode of claim 2, wherein the light-emitting diode is configured to emit light of one color by electrically connecting one pair of two adjacent electrodes from among the first electrode, the second electrode, the third electrode, and the fourth electrode to a driving layer.

9. The light-emitting diode of claim 1, further comprising at least one of:
a first compositionally graded layer under the first light-emitting cell;
a second compositionally graded layer between the first light-emitting cell and the second light-emitting cell; and
a third compositionally graded layer between the second light-emitting cell and the third light-emitting cell.

10. The light-emitting diode of claim 9, further comprising:
a first electrode in contact with the first compositionally graded layer;
a second electrode in contact with the second compositionally graded layer;
a third electrode in contact with the third compositionally graded layer; and
a fourth electrode in contact with the third light-emitting cell.

11. The light-emitting diode of claim 1, further comprising at least one of:
a first distributed Bragg reflector (DBR) layer provided on the first light-emitting cell and configured to reflect light of a second color emitted from the second light-emitting cell;
a second DBR layer provided on the second light-emitting cell and configured to reflect light of a third color emitted from the third light-emitting cell; or
a third DBR layer provided under the first light-emitting cell and configured to reflect light of a first color emitted from the first light-emitting cell.

12. The light-emitting diode of claim 1, wherein a width of the first light-emitting cell is greater than a width of the second light-emitting cell, and
wherein the width of the second light-emitting cell is greater than a width of the third light-emitting cell.

13. A display device comprising:
a display layer comprising a plurality of light-emitting diodes; and
a driving layer comprising a plurality of transistors electrically connected to the plurality of light-emitting diodes and configured to drive the plurality of light-emitting diodes,
wherein at least one of the plurality of light-emitting diodes comprises:
a first light-emitting cell, a second light-emitting cell, and a third light-emitting cell sequentially provided in one direction and configured to emit light of different colors from each other;
a first tunnel junction provided between the first light-emitting cell and the second light-emitting cell, the first tunnel junction being configured to electrically connect the first light-emitting cell and the second light-emitting cell and induce lateral current spreading; and
a second tunnel junction provided between the second light-emitting cell and the third light-emitting cell, the second tunnel junction being configured to electrically connect the second light-emitting cell and the third light-emitting cell and induce lateral current spreading.

14. The display device of claim 13, further comprising:
a first electrode in contact with the first light-emitting cell;
a second electrode in contact with the second light-emitting cell; and
a third electrode and a fourth electrode spaced apart from each other and in contact with the third light-emitting cell.

15. The display device of claim 14, wherein when the first electrode and the second electrode are electrically connected, the first light-emitting cell is configured to emit light of a first color,
wherein when the second electrode and the third electrode are electrically connected, the second light-emitting cell is configured to emit light of a second color, or
wherein when the third electrode and the fourth electrode are electrically connected, the third light-emitting cell is configured to emit light of a third color.

16. The display device of claim 13, further comprising at least one of:
a first compositionally graded layer under the first light-emitting cell;
a second compositionally graded layer between the first light-emitting cell and the second light-emitting cell; and
a third compositionally graded layer between the second light-emitting cell and the third light-emitting cell.

17. The display device of claim 16, further comprising:
a first electrode in contact with the first compositionally graded layer;
a second electrode in contact with the second compositionally graded layer;
a third electrode in contact with the third compositionally graded layer; and
a fourth electrode in contact with the third light-emitting cell.

18. The display device of claim 13, wherein the driving layer comprises a first region, a second region, and a third region that are alternately provided,
wherein each of the first region, the second region, and the third region comprises at least one well, and
wherein the plurality of light-emitting diodes provided in each well of the first region, the second region, and the third region are configured to emit light of different colors based on the provided regions, respectively.

19. A method of manufacturing a monolithic growth light-emitting diode configured to selectively emit one of first color light, second color light, and third color light based on connection of a first electrode, a second electrode, a third electrode, and a fourth electrode, the method comprising:
growing a first compositionally graded layer on a substrate;
growing a first light-emitting cell on the first compositionally graded layer;
sequentially forming a first tunnel junction and a first diffraction Bragg reflector (DBR) layer on the first light-emitting cell;
growing a second compositionally graded layer on the first DBR layer;
growing a second light-emitting cell on the second compositionally graded layer;
sequentially forming a second tunnel junction and a second DBR layer on the second light-emitting cell;
growing a third compositionally graded layer on the second DBR layer;
growing a third light-emitting cell on the third compositionally graded layer; and
forming the first electrode, the second electrode, and the third electrode in contact with the first compositionally graded layer, the second compositionally graded layer, and the third compositionally graded layer, respectively, and forming the fourth electrode on the third light-emitting cell.

20. A method of manufacturing a heterogeneous substrate bonding light-emitting diode configured to emit one of first color light, second color light, and third color light based on connection of a first electrode, a second electrode, a third electrode, and a fourth electrode, the method comprising:
growing a first element;
growing a second element;
bonding the first element and the second element;
removing a second substrate of the second element; and
forming an electrode,
wherein the growing of the first element comprises:
forming a third diffraction Bragg reflector (DBR) layer on a first substrate, growing a first light-emitting cell on the third DBR layer, and forming a first tunnel junction on the first light-emitting cell,
wherein the growing of the second element comprises:
growing a third compositionally graded layer on the second substrate;
growing a third light-emitting cell on the third compositionally graded layer;
growing a second compositionally graded layer on the third light-emitting cell;
sequentially forming a second DBR layer and a second tunnel junction on the second compositionally graded layer;
growing a second light-emitting cell on the second tunnel junction; and
forming a first DBR layer on the second light-emitting cell, and
wherein the forming of the electrode comprises:
forming the first electrode, the second electrode, and the third electrode in contact with the first light-emitting cell, the second light-emitting cell, and the third light-emitting cell, respectively; and
forming the fourth electrode on the third light-emitting cell.
